(19) United States
(12) Patent Application Publication
(10) Pub. No.: US 2016/0020166 A1
(43) Pub. Date: Jan. 21, 2016

(54) TRACE STRUCTURE OF FINE-PITCH PATTERN

(71) Applicant: CHIPBOND TECHNOLOGY CORPORATION, Hsinchu (TW)

(72) Inventors: Yung-Wei Hsieh, Hsinchu City (TW); Cheng-Hung Shih, Changhua County (TW); Kai-Yi Wang, New Taipei City (TW); Heh-Chang Huang, New Taipei City (TW); Po-Hao Chen, Chiayi County (TW)

(21) Appl. No.: 14/515,719

(22) Filed: Oct. 16, 2014

(30) Foreign Application Priority Data
Jul. 15, 2014 (TW) 103124328

(51) Int. Cl. H01L 23/50

(52) U.S. Cl. CPC H01L 23/50

(57) ABSTRACT

A trace structure of fine-pitch pattern includes a connection portion, a first conductive wire portion and a second conductive wire portion, the first conductive wire portion comprises a first section and a second section connected to the first section, the first section connects to the connection portion, the second conductive wire portion comprises a third section and a fourth section connected to the third section, the third section connects to the connection portion, wherein an etching space closed on three sides is formed by the connection portion, the third section and the first section, a first spacing is defined between the third section and the first section, a second spacing is defined between the fourth section and the second section, wherein the first spacing is larger than the second spacing so as to make an metal layer within the etching space completely removed to avoid metal layer residues.

### FIELD OF THE INVENTION

The present invention is generally relating to a trace structure, more particularly to the trace structure of fine-pitch pattern.

### BACKGROUND OF THE INVENTION

Owing to evolution of semiconductor process, the device on the semiconductor substrate and the trace distribution are inclined to be more and more compact. Particularly, in the fine-pitch pattern process, the width of the trace of the semiconductor substrate is 10 micro meters only, and the space between two adjacent traces is approximately 10 micro meters. Therefore, a conventional fine-pitch pattern process is selected from wet etching or dry etching for proceeding etching and patterning, wherein the dry etching is to utilize the gas ion (plasma) to remove unnecessary metal layer. However, the manufacturing cost of the dry etching is too high, it is more common to adopt wet etching for patterning trace layer in industry.

Wet etching is to utilize etching solution and metal layer for displacement reaction therefore removing unnecessary metal layer. The wet etching briefly describes as below: plating a metal layer on the semiconductor substrate; next, coating a photoresist layer on the metal layer; after that, exposure and developing the photoresist layer by a photo mask for patterning the photoresist layer; plating a trace layer on the exposed metal layer; removing the metal layer between the photoresist layer and traces so as to form the trace of the semiconductor substrate. However, in the process of fine-pitch pattern, expect the small width of the trace, the space between two traces is extremely small as well. Accordingly, the replaceability of the etching solution situated within the space closed on three sides between traces is weak so that the metal layer still remains within the space and is unable to remove completely.

### SUMMARY

The primary object of the present invention is to make a first spacing defined between a first section of a first conductive wire portion and a third section of a second conductive wire portion larger than a second spacing defined between a second section of a first conductive wire portion and a fourth section of a second conductive wire portion so that a etching space closed on three sides formed by a connection portion, the third section and the first section enables to perform complete etching therefore avoiding metal layer residues.

A trace structure of fine-pitch pattern of the present invention includes a connection portion, a first conductive wire portion and a second conductive wire portion. The second conductive wire portion electrically connects to the first conductive wire portion via the connection portion. Besides, the connection portion, the first conductive wire portion and the second conductive wire portion are the metal layers located on the same layer. The first conductive wire portion comprises a first section and a second section connected to the first section, wherein the first section connects to the connection portion, and the second section electrically connects to the connection portion via the first section. The second conductive wire portion comprises a third section and a fourth section connected to the third section, wherein the third section connects to the connection portion, and the fourth section electrically connects to the connection portion via the third section. An etching space closed on three sides is formed by the connection portion, the third section and the first section. A first spacing is defined between the third section and the first section, a second spacing is defined between the fourth section and the second section, and the first spacing is larger than the second spacing.

In this invention, by making the first spacing between the first section and the third section larger than the second spacing between the second section and the fourth section, the etching space closed on three sides formed by the connection portion, the third section and the first section enables to maintain excellent replaceability of the etching solution so that the metal layer within the etching space can be completely removed in etching process therefore avoiding metal layer residues.

### DESCRIPTION OF THE DRAWINGS

FIG. 1 is a partial top view illustrating a trace structure of fine-pitch pattern in accordance with a first embodiment of the present invention.

FIG. 2 is a partial perspective diagram illustrating the trace structure of fine-pitch pattern in accordance with the first embodiment of the present invention.

FIG. 3 is a partial top view illustrating the trace structure of fine-pitch pattern in accordance with a second embodiment of the present invention.

FIG. 4 is a partial perspective diagram illustrating the trace structure of fine-pitch pattern in accordance with the second embodiment of the present invention.

FIG. 5 is a partial top view illustrating a trace structure of fine-pitch pattern in accordance with a third embodiment of the present invention.

FIG. 6 is a partial perspective diagram illustrating the trace structure of fine-pitch pattern in accordance with the third embodiment of the present invention.

FIG. 7 is a partial top view illustrating a trace structure of fine-pitch pattern in accordance with a fourth embodiment of the present invention.

FIG. 8 is a partial perspective diagram illustrating the trace structure of fine-pitch pattern in accordance with the fourth embodiment of the present invention.

### DETAILED DESCRIPTION OF THE INVENTION

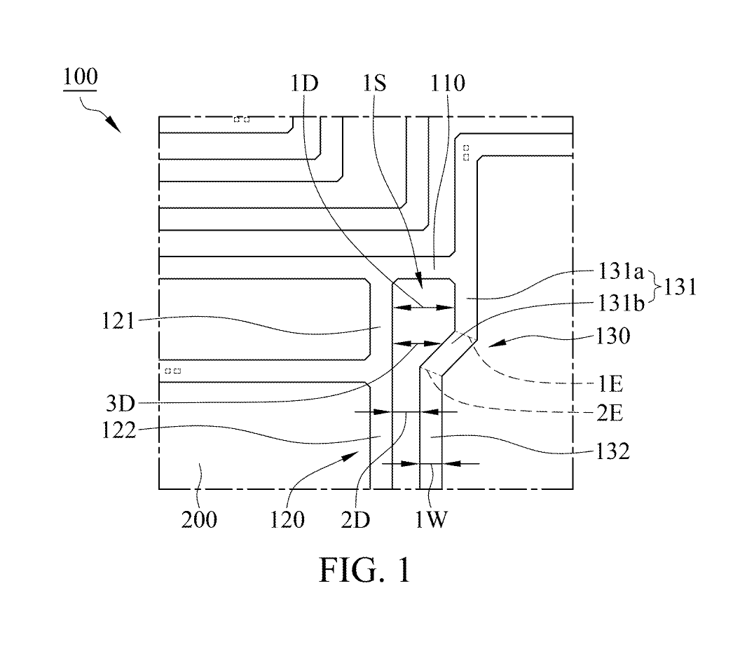

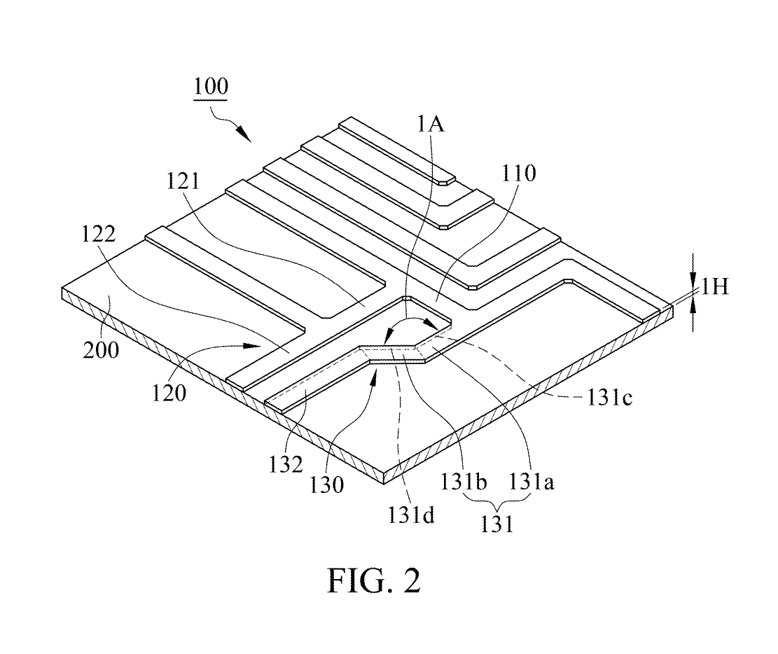

With reference to FIGS. 1 and 2, a trace structure of fine-pitch pattern 100 formed on a substrate 200 by etching process in accordance with an embodiment of the present invention includes a connection portion 110, a first conductive wire portion 120 and a second conductive wire portion 130. The connection portion 110, the first conductive wire portion 120 and the second conductive wire portion 130 are the metal layers located on the same layer and formed on the substrate 200 by a same process. Therefore, the second conductive wire portion 120 electrically connects to the first conductive wire portion 120 via the connection portion 110.

With reference to FIGS. 1 and 2, the first conductive wire portion 120 comprises a first section 121 and a second section 122 connected to the first section 121, wherein the first section 121 connects to the connection portion 110, and the second section 122 electrically connects to the connection portion 110 via the first section 121 for performing electric signal transmission.

With reference to FIGS. 1 and 2, the second conductive wire portion 130 comprises a third section 131 and a fourth section 132 connected to the third section 131, wherein the third section 131 connects to the connection portion 110, and the fourth section 132 electrically connects to the connection portion 110 via the third section 131 for performing electric signal transmission. An etching space 1S closed on three sides is formed by the connection portion 110, the third section 131 and the first section 121. In this embodiment, a width 1W of the second conductive wire portion 130 is 10 micro meter, a height 1H of the second conductive wire portion 130 is 10 micro meter, wherein the widths and the heights of the connection portion 110 and the first conductive wire portion 120 are the same with the second conductive wire portion 130. The present invention is not limited thereto.

With reference to FIG. 1, a first spacing 1D is defined between the third section 131 and the first section 121, a second spacing 2D is defined between the fourth section 132 and the second section 122, and the first spacing 1D is larger than the second spacing 2D. Owing to the first spacing 1D larger than the second spacing 2D, the etching space 1S enables to maintain better replaceability of the etching solution for prevention of metal layer residues after etching process.

With reference to FIGS. 1 and 2, in fine-pitch pattern, the widths, heights of the conductive wire portions and the size of the etching space 1S effect the replaceability of etching solution. Accordingly, in this embodiment, the ratio between the width 1W of the second conductive wire portion 130 and the first spacing 1D and the ratio between the width 1W and the height 1H of the second conductive wire 130 both define preferred values to prevent the etching space 1S from occurrence of metal layer residues after etching process. Preferably, the ratio between the width 1W of the second conductive wire portion 130 and the first spacing 1D ranges from 1:2 to 1:3, and the ratio between the width 1W and the height 1H of the second conductive wire portion 130 ranges from 1:0.8 to 1:1.2 so as to make metal layer within the etching space 1S completely removed in the process of etching.

Referring to FIGS. 1 and 2, the third section 131 of the second conductive wire portion 130 comprises a straight portion 131a and a bent portion 131b connected to the straight portion 131a and the forth section 132, the straight portion 131a connects to the connection portion 110 and comprises a first lateral surface 131c, the bent portion 131b comprises a second lateral surface 131d, wherein the first lateral surface 131c and the second lateral surface 131d both face toward the etching space 1S. An included angle 1A is defined between the first lateral surface 131c and the second lateral surface 131d, and the first included angle 1A is smaller than 180 degrees. In this embodiment, the metal residues occur between the straight portion 131a and the bent portion 131b after etching process by cause of the first included angle 1A smaller than 90 degrees. Therefore, preferably, the metal residues between the straight portion 131a and the bent portion 131b can be completely removed once the first included angle 1A is ranged from 90 to 180 degrees.

With reference to FIGS. 1 and 2, the bent portion 131b comprises a first terminal 1E and a second terminal 2E connected to the fourth section 132, the first terminal 1E connects to the straight portion 131a, wherein a third spacing 3D is defined between the second lateral surface 131d of the bent portion 131b and the first section 121, the third spacing 3D is tapered gradually from the first terminal 1E to the second terminal 2E in order to strive for larger wiring area or disposing area of an apparatus.

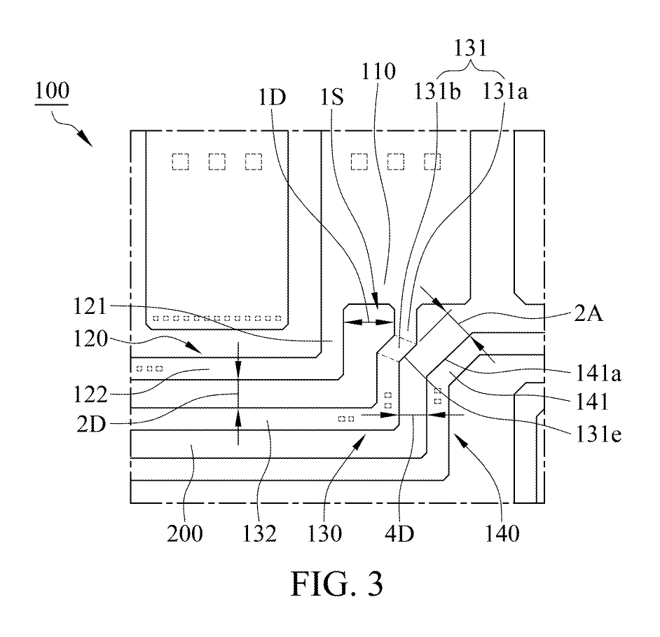

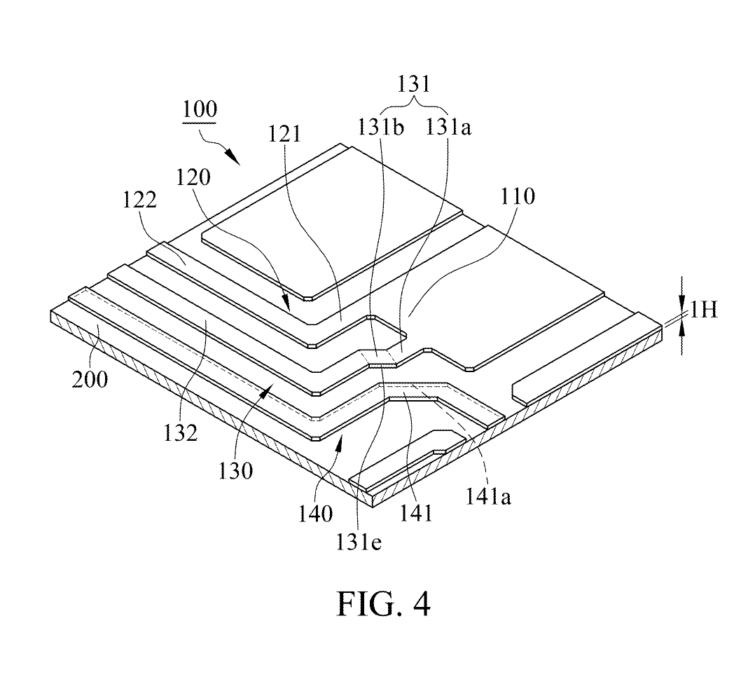

A second embodiment of the present invention is illustrated in FIGS. 3 and 4. The primary difference between the second embodiment and the first embodiment is that the trace structure of fine-pitch pattern 100 further includes a third conductive wire portion 140, wherein the second conductive wire portion 130 is located between the first conductive wire portion 120 and the third conductive wire portion 140, furthermore, a fourth spacing 4D is defined between the third conductive wire portion 140 and the second conductive wire portion 130, and the fourth spacing 4D is not smaller than the second spacing 2D so as to prevent the spacing between the second conductive wire portion 130 and the third conductive wire portion 140 from being lower than the second spacing 2D therefore avoiding incomplete etching of metal layer.

With reference to FIGS. 3 and 4, the third conductive wire portion 140 comprises an abdication section 141, the bent portion 131b comprises a third lateral surface 131e facing toward the third conductive wire portion 140, the abdication section 141 comprises a fourth lateral surface 141a, wherein a second included angle 2A is defined between the fourth lateral surface 141a and the third lateral surface 131e, and the second included angle 2A is smaller than 1 degree. The bent portion 131b of the second conductive wire portion 130 and the abdication section 141 of the third conductive wire portion 140 are arranged in parallel arrangement to prevent the spacing between the bent portion 131b and the abdication section 141 from excessively small.

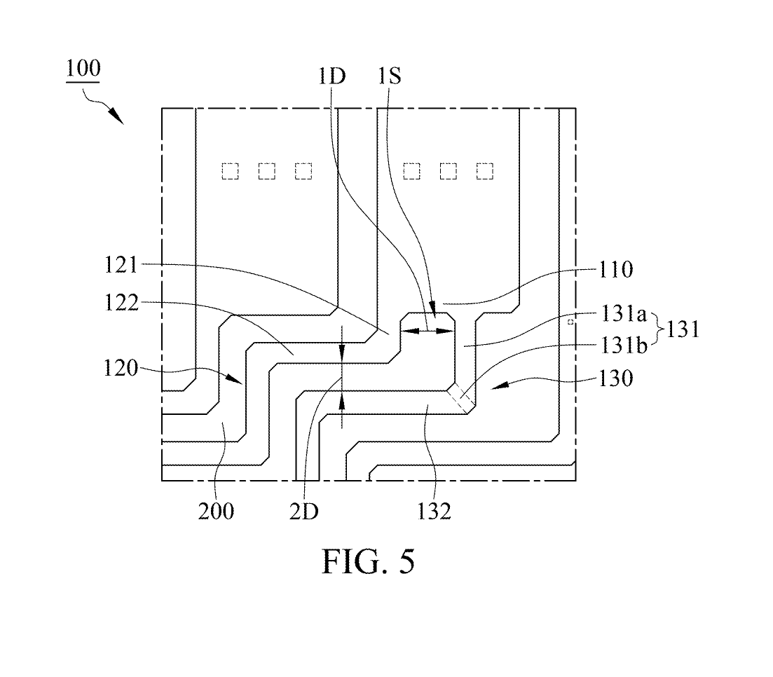

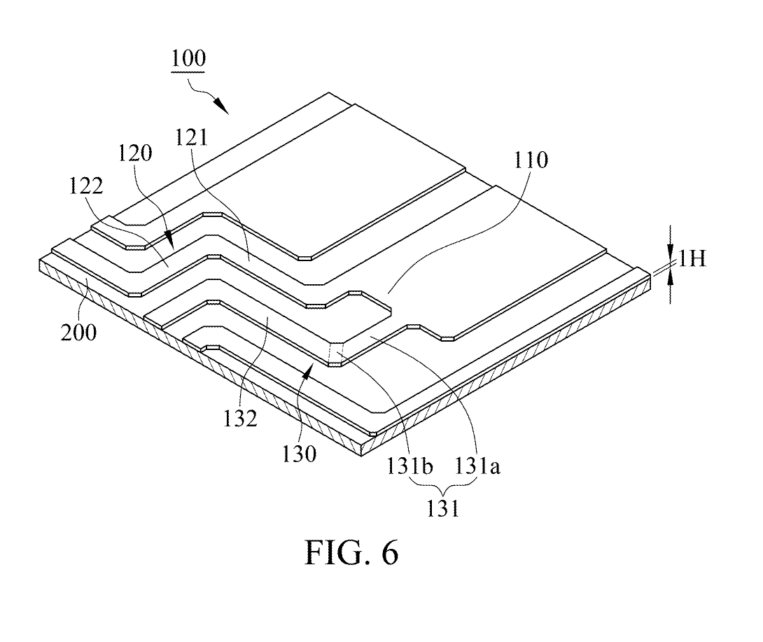

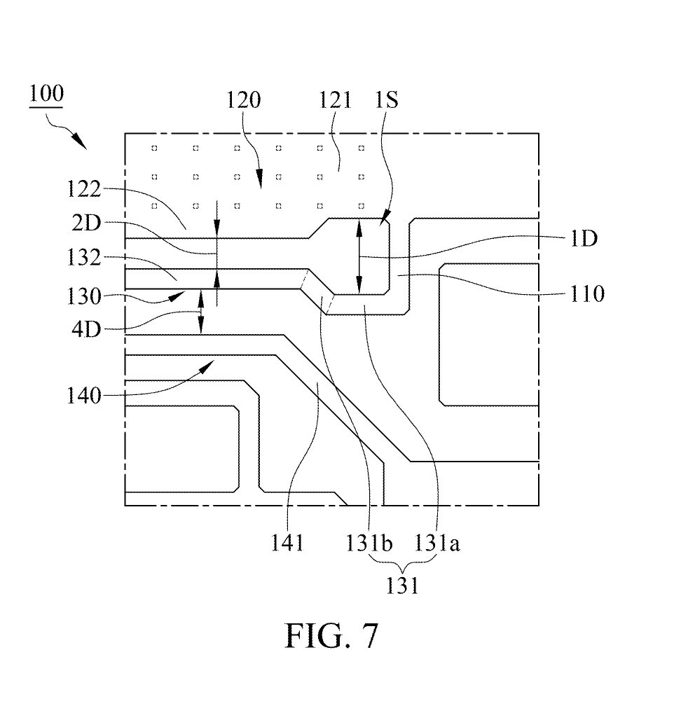

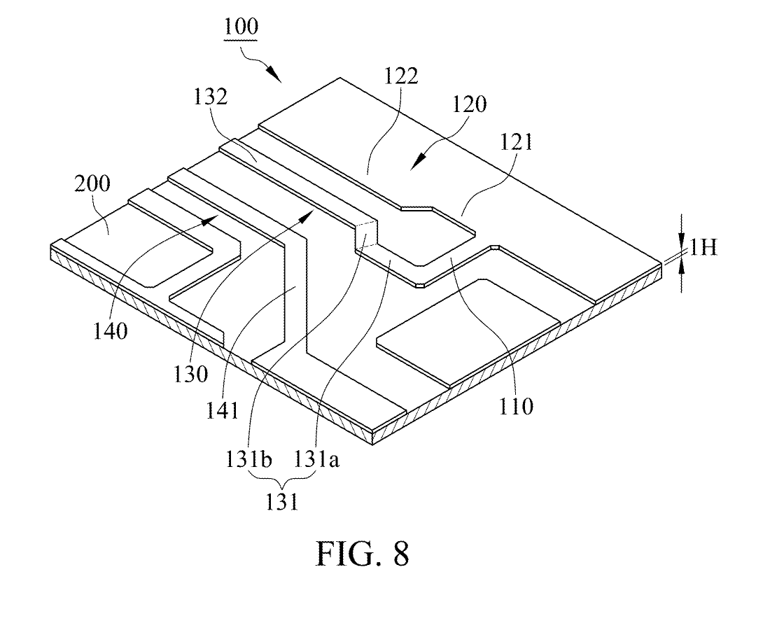

A third embodiment and a fourth embodiment are illustrated in FIGS. 5, 6, 7 and 8 separately. Simultaneously, in the third embodiment and the fourth embodiment, the first spacing 1D between the third section 131 and the first section 121 is larger than the second spacing 2D between the fourth section 132 and the second section 122 so that incomplete etching for the metal layer within the etching space 1S will not occur.

By the first spacing 1D from the third section 131 to the first section 121 larger than the second spacing 2D from the fourth section 132 to the second section 122, the present invention enables the etching space 1S closed on three sides to be formed by the connection section 110, the third section 131 and the first section 121 and enables to maintain excellent replaceability of the etching solution so that the metal layer within the etching space can be completely removed in etching process therefore avoiding metal layer residues.

While this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

What is claimed is:

1. A trace structure of fine-pitch pattern includes:
a connection portion;
a first conducting wire portion having a first section and a second section connected to the first section, wherein the first section connects to the connection portion, the second section electrically connects to the connection portion via the first section; and
a second conductive wire portion electrically connected to the first conductive wire portion via the connection portion, wherein the connection portion, the first conductive wire portion and the second conductive wire portion are the metal layers located on the same layer, the second conductive wire portion comprises a third section and a fourth section connected to the third section, wherein an etching space closed on three sides is formed by the connection portion, the third section and the fourth section, the fourth section electrically connects to the connection portion via the third section, wherein a first spacing is defined between the third section and the first section, a second spacing is defined between the fourth section and the second section, the first spacing is larger than the second spacing.

2. The trace structure of fine-pitch pattern in accordance with claim 1, wherein the third section of the second conductive wire portion comprises a straight portion and a bent portion connected to the straight portion and the forth section, the straight portion connects to the connection portion and comprises a first lateral surface, the bent portion comprises a second lateral surface, wherein the first lateral surface and the second lateral surface both face toward the etching space, an included angle is defined between the first lateral surface and the second lateral surface, and the first included angle is smaller than 180 degrees.

3. The trace structure of fine-pitch pattern in accordance with claim 2, wherein the first included angle is in the range from 90 to 180 degrees.

4. The trace structure of fine-pitch pattern in accordance with claim 2, wherein the bent portion comprises a first terminal and a second terminal connected to the fourth section, the first terminal connects to the straight portion, wherein a third spacing is defined between the second lateral surface of the bent portion and the first section, the third spacing is tapered gradually from the first terminal to the second terminal.

5. The trace structure of fine-pitch pattern in accordance with claim 1, wherein the second conductive wire portion comprises a width, and the ratio of the width to the first spacing is in the range from 1:2 to 1:3.

6. The trace structure of fine-pitch pattern in accordance with claim 5, wherein the second conductive wire portion comprises a height, and the ratio of the width to the height is in the range from 1:0.8 to 1:1.2.

7. The trace structure of fine-pitch pattern in accordance with claim 1 further includes a third conductive wire portion, the second conductive wire portion is located between the first conductive wire portion and the third conductive wire portion, wherein a fourth spacing is defined between the third conductive wire portion and the second conductive wire portion, and the fourth spacing is not smaller than the second spacing.

8. The trace structure of fine-pitch pattern in accordance with claim 2 further includes a third conductive wire portion, the second conductive wire portion is located between the first conductive wire portion and the third conductive wire portion, the third conductive wire portion comprises an abdication section, the bent portion comprises a third lateral surface facing toward the third conductive wire portion, the abdication section comprises a fourth lateral surface, wherein a second included angle is defined between the fourth lateral surface and the third lateral surface, and the second included angle is smaller than 1 degree.
